(19) United States
(12) Patent Application Publication
(10) Pub. No.: US 2009/0154082 A1
(43) Pub. Date: Jun. 18, 2009

(54) Electronic device, computer porgram product and control method

(76) Inventors: Mikko Nurmi, Tampere (FI); Sanna Koskinen, Tampere (FI); Katja Konkka, Tampere (FI); Sanna Lindroos, Valkeakoski (FI); Rutta Jokela, Ramsoo (FI); Paivi Heikkila, Tampere (FI)

Correspondence Address: Hollingsworth & Funk, LLC, 8009 34th Avenue South, Suite 125, Minneapolis, MN, 54425, US

(21) Appl. No.: 11/991,330

(22) PCT Filed: Sep. 30, 2005
(86) PCT No.: PCT/FI2005/050340

§ 371 Date: Feb. 29, 2008

(51) Int. Cl. H05K 5/02

(52) U.S. Cl. 361/679.3

(57) ABSTRACT

There is provided an electronic device comprising: a body, a slidable element connected to the body, a display connected to the body for displaying application views, and a processing unit for controlling functions of the electronic device, wherein the slidable element is slidable between a closed position and an open position relative to the body. The processing unit is configured to detect an occurrence of one or more intermediate positions of the slidable element relative to the body, the intermediate positions being associated with one or more application views and residing between the closed position and the open position; and to control which predetermined application view is displayed on the display on the basis of the detected occurrence of one or more intermediate positions of the slidable element.

### FIELD

The invention relates to a method of controlling functions of an electronic device, to an electronic device, to a computer program product, and to a computer program distribution medium.

### BACKGROUND

Electronic devices with different sliding elements or covers are known. Such sliding elements can be, for example, slidable covers that protect the keyboard or the display of the device during transportation. It is usual that as the sliding element of the device is in a closed position, the keyboard or the display is at least partly hidden. Accordingly, as the sliding element of the device is in an open position, the keyboard and the display are visible. A common usage of the sliding element is that while the sliding element is in an open position, an application view is shown on the display of the device different than that being shown when the sliding element is in a closed position. However, no solutions for other possibilities for controlling functions of the device by using the sliding element exist. Thus, not all capacity of the sliding elements is utilized.

### BRIEF DESCRIPTION OF THE INVENTION

An object of the invention is to provide an improved method of controlling functions of an electronic device, an improved electronic device, an improved computer program product, and a computer program distribution medium.

According to an aspect of the invention, there is provided a method of controlling functions of an electronic device, the electronic device comprising: a body, a display connected to the body for displaying application views, and a slidable element connected to the body, the slidable element being slidable between a closed position and an open position relative to the body. The method comprises: detecting an occurrence of one or more intermediate positions of the slidable element relative to the body, the intermediate positions being associated with one or more application views and residing between the closed position and the open position; and controlling which predetermined application view is displayed on the display on the basis of the detected occurrence of one or more intermediate positions of the slidable element.

According to another aspect of the invention, there is provided electronic device comprising: a body, a slidable element connected to the body, a display connected to the body for displaying application views, and a processing unit for controlling functions of the electronic device, wherein the slidable element is slidable between a closed position and an open position relative to the body. The processing unit is configured to detect an occurrence of one or more intermediate positions of the slidable element relative to the body, the intermediate positions being associated with one or more application views and residing between the closed position and the open position; and to control which predetermined application view is displayed on the display on the basis of the detected occurrence of one or more intermediate positions of the slidable element.

According to another aspect of the invention, there is provided a computer program product encoding a computer program of instructions for executing a computer process for controlling functions of an electronic device, the electronic device comprising: a body, a slidable element connected to the body, and a display connected to the body for displaying application views, wherein the slidable element is slidable between a closed position and an open position relative to the body. The process comprises: detecting an occurrence of one or more intermediate positions of the slidable element relative to the body, the intermediate positions being associated with one or more application views and residing between the closed position and the open position; and controlling which predetermined application view is displayed on the display on the basis of the detected occurrence of one or more intermediate positions of the slidable element.

According to another aspect of the invention, there is provided a computer program distribution medium readable by a computer and encoding a computer program of instructions for executing a computer process for controlling functions of an electronic device, the electronic device comprising: a body, a slidable element connected to the body, and a display connected to the body for displaying application views, wherein the slidable element is slidable between a closed position and an open position relative to the body. The process comprises: detecting an occurrence of one or more intermediate positions of the slidable element relative to the body, the intermediate positions being associated with one or more application views and residing between the closed position and the open position; and controlling which predetermined application view is displayed on the display on the basis of the detected occurrence of one or more intermediate positions of the slidable element.

The invention provides several advantages. Easy access to different functions of the device is enabled. The full capacity of the slidable element can effectively be utilized in a functional way.

### LIST OF DRAWINGS

In the following, the invention will be described in greater detail with reference to embodiments and the accompanying drawings, in which

FIG. 1 shows an example of an electronic device;

FIGS. 2A, 2B and 2C show examples of an electronic device;

FIGS. 3A, 3B and 3C show more examples of an electronic device; and

FIG. 4 is a flowchart illustrating an example of a method of controlling functions of an electronic device.

### DESCRIPTION OF EMBODIMENTS

The invention may be applied to electronic devices, such as a mobile station, used as a terminal device in telecommunication systems comprising one or more base transceiver stations and terminal devices communicating with the base transceiver stations. In some embodiments of the invention, such a device comprises a possibility of short-range communication, such as a Bluetooth chip or a transceiver functionality implemented by an infrared or a WLAN connection. The electronic device is e.g. a mobile telephone, a computer, a handheld computer, a communication device, or an intelligent telephone. The invention may also be applied to PDA (Personal Digital Assistant) devices which themselves comprise the necessary telecommunication properties, or to PDA devices which may be connected e.g. to a mobile telephone for a network connection. The electronic device may also be a computer or a PDA device comprising no telecommunication properties.

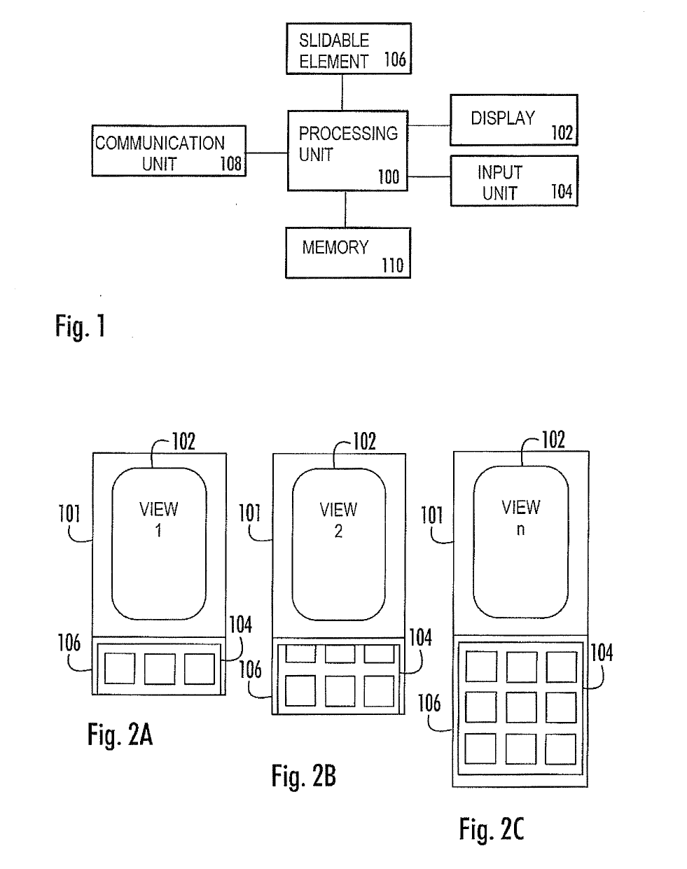

FIG. 1 is a block diagram showing a structure of an electronic device. A processing unit 100, which is typically implemented by means of a microprocessor, a signal processor or separate components and associated software, controls the basic functions of the device. A user interface of the device comprises an input unit 104 and a display 102. Typically, the display 102 is a liquid crystal display. The input unit 104 may comprise e.g. a mouse or a keypad. The display 102 itself can also be the input unit 104 and comprise, for example, a touch screen.

The device may further comprise several other user interface parts, which may differ in kind and number, depending on the type of the device. The electronic device shown in FIG. 1, such as a mobile station, may also comprise communication means 108, which include speech and channel coders, modulators and RF parts, to implement the functions of the device. The device may further comprise a memory 110.

The electronic device further comprises a slidable element 106, such as a cover, that is slidably connected to the body of the device. The slidable element 106 can be slidable between a closed position and an open position relative to the body of the device. The display 102 and/or the input unit 104 can be provided on the slidable element. When the slidable element 106 is in its closed position, at least part of the display 102 and/or the keypad is hidden. When the slidable element 106 is in its open position, the display 102 and/or the input unit 104 is completely revealed. Thus, the slidable element 106 can be movable over the display 102 and/or over the keypad part of the device.

The processing unit 100 is configured to detect current positions of the slidable element, for example, via sensors between the slidable element and the body of the device. The processing unit 100 can be configured to show predetermined application views or information on the display 102, depending on the current position of the slidable element 106. Thus, when the slidable element 106 is in its closed position, information can be shown on the display 102 different from that being shown when the slidable element 106 is in its open position.

In an embodiment, the processing unit 100 is configured to detect occurrence of one or more intermediate positions of the slidable element 106 relative to the body, the intermediate positions being associated with one or more application views and located between the closed position and the open position; and to control which predetermined application view is displayed on the display 102 on the basis of the detected occurrence of one or more intermediate positions of the slidable element 106.

In practice, as the slidable element 106 is moved relative to the body of the device, different application views/functions/information can be displayed on the display 102, depending on the current intermediate position of the slidable element 106. The displayed application views/functions/information may be active or non-active programs, reminders, views to Internet pages, messages, phone call logs, missed calls, calendar notes, different functions of application programs, recent calls, contacts, lists of different information, lists of applications last used, lists of active/open applications, speed dials etc. There may be as many intermediate positions as possible available between the open position and the closed position. Besides a visual display, different intermediate positions of the slidable element can be made more clearly identifiable, for example, by providing any kind of identification, such as sounds or “a click” of the slidable element each time an intermediate position is entered. The user of the device may freely select which application views or functions are associated to predetermined intermediate positions of the slidable element. Table 1 shows, as an example, which application views can be associated to specific positions of the slidable element.

TABLE 1

| Position of slidable element | Displayed application view/function |
|---|---|
| Closed position | Clock |
| Intermediate position 1 | Received mail |
| Intermediate position 2 | MP3 player |
| Intermediate position 3 | Camera |
| Intermediate position 4 | Way-finder |
| Open position | Normal user interface |

From the example of Table 1, it can be seen that when the slidable element is in its closed position, a clock application is shown on the display of the device. In a closed position, for example, only a small part of the display may be visible and thus, it is not meaningful to show application views requiring more space on the display. As the slidable element is moved to the first intermediate position, the processing unit is configured to display received mail information on the display. An MP3 player is activated when the processing unit detects that the slidable element is in the second intermediate position, and a camera application is launched in the third intermediate position. In the example of Table 1, a way-finder application is displayed on the fourth intermediate position, and a common user interface is shown when the slidable element is detected to be in the open position.

It is possible that when the slidable element is moved towards the closed position, the displayed application views are the same as when the slidable element is moved towards the open position but only in the reversed order. On the other hand, the displayed application views can be completely different, depending on the direction in which the slidable element is moved.

In an embodiment, the processing unit 100 is configured to maintain a current application view on the display 102 when a selection function is detected while the slidable element 106 is in a given intermediate position; and to activate an application related to the maintained application view once the slidable element has reached the open position or the closed position. Thus, for example in the case of Table 1, if the user wishes to start using the camera application, he/she may first slide the slidable element to the third intermediate position and then select the camera application, for example, by pushing a selection key. After that, the user may continue sliding the slidable element 106 to the open position or to the closed position, where the camera application is finally activated.

In another embodiment, the processing unit 100 is configured to activate an application related to the displayed application view when the slidable element 106 is in an intermediate position associated with the displayed application view. Thus, for example, the camera application is activated once the user has moved the slidable element 106 to the third intermediate position that is associated with the camera application. The processing unit 100 may further be configured to detect that the slidable element 106 has remained in the given intermediate position for a predetermined period of time before activating the application related to the displayed application view. Thus, if the user quickly wishes to activate a camera application, he/she may move the slidable element 106 directly to the third intermediate position and maintain the third intermediate position for a predetermined period of time in order to activate the camera application.

In an embodiment, the processing unit 100 is configured to detect whether the slidable element 106 has entered the intermediate position from the direction of the closed position or the open position, and to control which application view is displayed on the display 102 on the basis of detecting the direction from which the intermediate position was entered. Table 2 shows an example where the displayed application view/function is dependent on the direction from which the intermediate position of the slidable element 106 is entered.

TABLE 2

| | Displayed application | Displayed application |
|---|---|---|
| | view/function when | view/function when |
| | intermediate position | intermediate position |
| Intermediate position | entered from direction | entered from direction |
| of slidable element | of closed position | of open position |
| Intermediate position 1 | Received mail | Way finder |
| Intermediate position 2 | Reminder | Time dependent function |
| Intermediate position 3 | Camera | Camera |
| Intermediate position 4 | MP3 player | Calendar |
| Intermediate position 5 | Internet page | Reminder |

As seen from Table 2, the application view/function associated with a specific intermediate position may be different when the intermediate position is entered from different directions. The displayed application view/function when the first intermediate position is entered from the direction of the closed position is Received mail. On the other hand, when the first intermediate position is entered from the direction of the open position, the displayed application view is Way finder. Further, the displayed application view when the second intermediate position is entered from the direction of the closed position is a view to a Reminder application. The displayed application views/functions can also be time-dependent. Thus, depending on the date and/or time of day, the displayed application views associated with specific intermediate positions may vary. This can also be seen in the example of Table 2, where the displayed application view/function are time dependent when the second intermediate position is entered from the direction of open position. For example, it can be set that between 8 a.m. and 10 a.m. the displayed application view is a Clock application and something else at other times. It is also possible that during certain periods of time no application views/functions are displayed when a specific intermediate position of the slidable element is detected. It can be seen in Table 2 that the displayed application view/function can also be the same, irrespective of the direction from which the intermediate position is entered. In this example, the displayed application view/function when the third intermediate position is entered from any direction is Camera application.

Further, it is possible that the functions of different application programs are controlled similarly by moving the slidable element. For example, after the user has selected/activated a given application, for example, the Camera application, by sliding the slidable element to an intermediate position associated with the Camera application, the user may continue controlling the functions of the Camera application by further moving the slidable element to intermediate positions that are associated with the functions of the Camera application. When a Calendar application is active, different application views of the Calendar application may be displayed, depending on the position of the slidable element. For example, in a predetermined position of the slidable element, a day view may be shown. The predetermined position can then be an open position, any intermediate position, or a closed position. In another position of the slidable element, a week view can be shown and in yet another position of the slidable element, a month view can be shown, for example. In different positions of the slidable element, the shown display size and keys can be used according to the position.

The software operating instructions encoding the computer process for the method of controlling functions of an electronic device may be stored in the memory 110 of the device. In an embodiment, the computer process further comprises: detecting an occurrence of one or more intermediate positions of the slidable element relative to the body, the intermediate positions being associated with one or more application views and being between the closed position and the open position; and controlling which predetermined application view is displayed on the display on the basis of the detected occurrence of one or more intermediate positions of the slidable element.

It is possible that the intermediate positions are associated with specific application views in the manufacturing stage of the device. However, the users of the device, according to their current needs, may also execute the associations of the intermediate positions with the application views. The input unit 104 can be used for associating the intermediate positions with the application views or for modifying the associations already made at any time.

FIGS. 2A, 2B and 2C show examples of an electronic device. In the examples of FIGS. 2A, 2B and 2C, the electronic device has a body part 101 that includes a display 102 for showing application views. The electronic device further comprises a slidable element 106 electrically connected to the body 101. In these examples, the slidable element 106 further comprises an input unit 104, here a keypad part.

The slidable element 106 is slidable between a closed position and an open position relative to the body 101. FIG. 2A shows the electronic device in a state where the slidable element 106 in a closed position. In the closed position, most of the keypad part is hidden. It is also possible that the whole keypad part is hidden in the closed position. The closed position here means that the slidable element 106 cannot be moved any more to reduce the visible area of the keypad part. As can be seen from FIG. 2A, an application view 1 is displayed on the display 102.

FIG. 2B shows the electronic device in a state where the slidable element 106 is in an intermediate position. In the intermediate position, more of the keypad part is revealed than in the closed position, but not all of it. There may be several different intermediate positions for the slidable element 106 to be in. Application view 2 is displayed on the display 102 while the slidable element 106 is the intermediate position.

FIG. 2C shows the electronic device in a state where the slidable element 106 is in an open position. In the open position, the whole keypad part is now visible. Application view n is displayed on the display 102 when the slidable element 106 is in the open position. The displayed application views may be different each time the intermediate position changes. The displayed application views may also vary depending on the time of the day. Also the application views displayed in the open position and in the closed position may vary depending on different circumstances. For example, the displayed application view may be set to change if new calls are received or a meeting about to begin shortly is marked in a calendar. Further, a setting is possible wherein depending on the time of the day different Internet pages are loaded when the slidable element is in a given intermediate position.

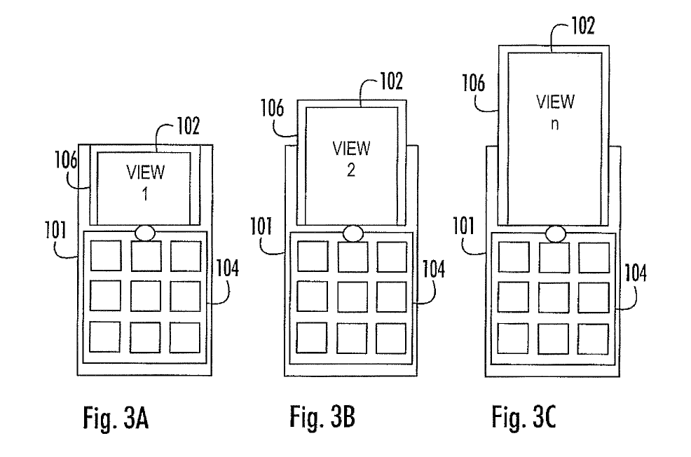

FIGS. 3A, 3B and 3C show further examples of an electronic device. In the examples of FIGS. 3A, 3B and 3C, the electronic device has a body 101 that now includes a keypad part 104. The electronic device further comprises a slidable element 106 connected to the body 101. In these examples, the slidable element 106 further comprises a display 102. The examples in these illustrative figures are only simplified examples. The device with the slidable element 106 can naturally be implemented in any other ways possible.

The slidable element 106 can again be moved between a closed position (shown in FIG. 3A) and an open position (shown in FIG. 3C). In the closed position, only a small part of the display 102 is visible. In the open position, the whole display 102 is visible. Application view 1 is displayed on the display 102 when the slidable element 106 is in the closed position. Since only a small part of the display 102 is visible, it would be appropriate to show application views not requiring too much space, such as an indication of time, for example. In an open position, application view n is displayed on the display 102.

In the intermediate position (illustrated in FIG. 3B), a larger part of the display 102 is visible than in the closed position, but not all of it. Application view 2 is displayed on the display 102 in the intermediate position. There may be several intermediate positions available between the open and the closed positions.

Besides the examples of FIGS. 2A, 2B, 2C, 3A, 3B, 3C, the slidable element 106 can be slidable in any other ways related to the body 101 of the device. There may also be more than one slidable elements 106 in just one device. It is possible that sliding of a slidable element 106 uncovers another display, a touch sensitive area or any other parts of the device. Further, the slidable element 106 can be slidable such that it comes forward from any sides of the device. The slidable element 106 can, for example, be implemented by using a swivel type mechanism. Thus, turning or rotating the slidable element rather than sliding it can move the slidable element 106 in relation to the body of the device.

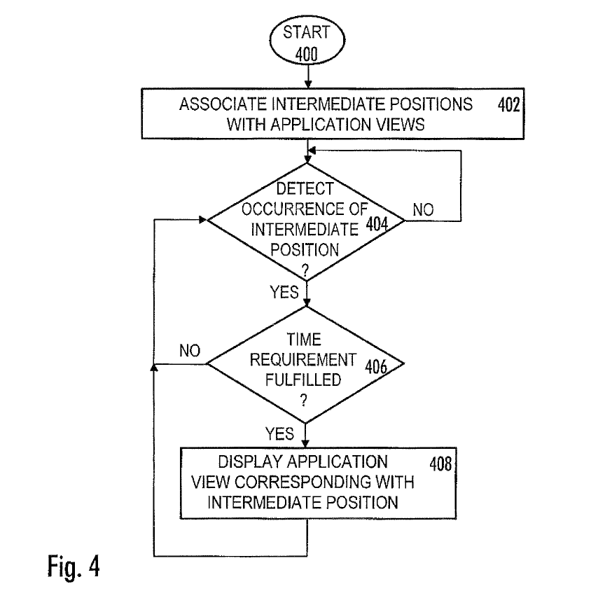

FIG. 4 is a flowchart illustrating an example of a method of controlling functions of an electronic device. The method starts in 400. In 402, one or more intermediate positions of a slidable element relative to the body of the device are associated with one or more application views. The intermediate positions reside between the closed position and the open position.

In 404, an occurrence of any intermediate position of the slidable element is detected. If an intermediate position of the slidable element is detected, the process may continue directly to 408 where an application view associated with the intermediate position is displayed on the display of the device. Before entering 408, it is also possible to detect in 406 whether a specified time requirement is fulfilled, i.e. whether or not the slidable element has remained in the given intermediate position for a predetermined period of time. Thus, if the user wishes to proceed directly to an application view associated with a second intermediate position, he/she can move the slidable element with a continuous movement to the second intermediate position without the application view changing at the location of the first intermediate position. It is also possible that a particular application view being displayed only includes information about the corresponding application, and that only after a predetermined time has lapsed in the given intermediate position will the corresponding application be activated. The users of the device may also select a specific application they wish to use by pressing a selection key at a moment when the slidable element is in an intermediate position associated with that specific application. This selection then activates the application immediately or after the user has stopped moving the slidable element to any desired position.

After 408, the processing unit of the device may continue detecting occurrences of any intermediate position of the slidable element and displaying corresponding application views. It is also possible that after the application corresponding with the application view associated to a specific intermediate position has been activated, the slidable element may be used for controlling functions or application views of the selected application itself. For example, the functions of a messaging application can be controlled by detected intermediate positions of the slidable element. Thus, when the messaging application is activated, a received message view can be displayed in an open position of the slidable element. Further, in some intermediate position of the slidable element, an indication and a soft notification of the received message can be displayed. In another intermediate position, an application for editing the message can be activated for enabling the user to edit a message.

The embodiments of the invention may be implemented in an electronic device comprising a processing unit operationally connected to an input unit, to a display and to a slidable element, for example. The processing unit may be configured to perform at least some of the steps described in connection with the flowchart of FIG. 4. The embodiments may be implemented as a computer program comprising instructions for executing a computer process for controlling functions of an electronic device.

The computer program may be stored on a computer program distribution medium readable by a computer or a processor. The computer program medium may be, for example but not limited to, an electric, magnetic, optical, infrared or semiconductor system, device or transmission medium. The medium may be a computer readable medium, a program storage medium, a record medium, a computer readable memory, a random access memory, an erasable programmable read-only memory, a computer readable software distribution package, a computer readable signal, a computer readable telecommunications signal, and a computer readable compressed software package.

Even though the invention has been described above with reference to an example according to the accompanying drawings, it is clear that the invention is not restricted thereto but it can be modified in several ways within the scope of the appended claims.

1. A method, comprising:
controlling functions of an apparatus, the apparatus comprising: a body, a display connected to the body for displaying application views, and a slidable element connected to the body, the slidable element being slidable between a closed position and an open position relative to the body;
detecting an occurrence of one or more intermediate positions of the slidable element relative to the body, the intermediate positions being associated with one or more application views and residing between the closed position and the open position;
controlling which predetermined application view is displayed on the display on the basis of the detected occurrence of one or more intermediate positions of the slidable element;
varying the one or more application views associated with the intermediate positions on the basis of a moment in time; and
selecting the application view to be displayed depending on the moment in time when the one or more intermediate positions are detected.

2. The method of claim 1, the method further comprising: maintaining a current application view on the display when a selection function is detected while the slidable element is in a given intermediate position; and activating an application related to the maintained application view once the slidable element has reached the open position or the closed position.

3. The method of claim 1, the method further comprising activating an application related to the displayed application view when the slidable element is in an intermediate position associated with the displayed application view.

4. The method of claim 3, the method further comprising detecting that the slidable element has remained in the given intermediate position for a predetermined period of time before activating the application related to the displayed application view.

5. The method of claim 2, wherein after the activation of the application the method further comprises detecting an occurrence of an open position, a closed position or at least one intermediate position of the slidable element relative to the body, the positions being associated with one or more application views of the activated application; and controlling which predetermined application view of the activated application is displayed on the display on the basis of the detected occurrence of one or more positions of the slidable element.

6. The method of claim 1, the method further comprising detecting whether the slidable element has entered the intermediate position from the direction of the closed position or the open position, and the step of controlling which application view is displayed on the display being further based on the detection of the direction from which the intermediate position has been entered.

7. The method of claim 5, wherein when the slidable element has entered the intermediate position from the direction of the closed position the predetermined application view displayed on the display is different from that being displayed when the intermediate position is entered from the direction of the open position.

8. An apparatus, comprising:
a body, a slidable element connected to the body, a display connected to the body for displaying application views;
a processing unit configured to control functions of the apparatus, wherein the slidable element is slidable between a closed position and an open position relative to the body, the processing unit is further configured to:
detect an occurrence of one or more intermediate positions of the slidable element relative to the body, the intermediate positions being associated with one or more application views and residing between the closed position and the open position;
control which predetermined application view is displayed on the display on the basis of the detected occurrence of one or more intermediate positions of the slidable element;
vary the one or more application views associated with the intermediate positions on the basis of a moment in time; and
select the application view to be displayed depending on the moment in time when the one or more intermediate positions are detected.

9. The apparatus of claim 8, wherein the processing unit is configured to maintain a current application view on the display when a selection function is detected while the slidable element is in a given intermediate position; and to activate an application related to the maintained application view once the slidable element has reached the open position or the closed position.

10. The apparatus of claim 8, wherein the processing unit is further configured to activate an application related to the displayed application view when the slidable element is in an intermediate position associated with the displayed application view.

11. The apparatus of claim 10, wherein the processing unit is configured to detect that the slidable element has maintained in the given intermediate position for a predetermined period of time before activating the application related to the displayed application view.

12. The apparatus of claim 9, wherein after the activation of the application, the processing unit is configured to detect an occurrence of an open position, a closed position or at least one intermediate position of the slidable element relative to the body, the positions being associated with one or more application views of the activated application; and controlling which predetermined application view of the activated application is displayed on the display on the basis of the detected occurrence of one or more positions of the slidable element.

13. The apparatus of claim 8, wherein the processing unit is configured to detect whether the slidable element has entered the intermediate position from the direction of the closed position or the open position, and to control which application view is displayed on the display on the basis of the detection of the direction from which the intermediate position is entered.

14. The apparatus of claim 12, wherein the displayed predetermined application views associated with the intermediate positions of the slidable element are the same, but in reverse order, depending on which direction the intermediate position is entered.

15. The apparatus of claim 12, wherein when the slidable element has entered the intermediate position from the direction of the closed position the predetermined application view displayed on the display is different from that being displayed when the intermediate position is entered from the direction of the open position.

16. The apparatus of claim 8, wherein the display resides on the slidable element.

17. The apparatus of claim 8, wherein the display resides on the body.

18. An apparatus comprising processing means for:
controlling functions of the apparatus comprising a body, a slidable element connected to the body wherein the slidable element is slidable between a closed position and an open position relative to the body, and a display connected to the body for displaying application views;
detecting an occurrence of one or more intermediate positions of the slidable element relative to the body, the intermediate positions being associated with one or more application views and residing between the closed position and the open position;
controlling which predetermined application view is displayed on the display on the basis of the detected occurrence of one or more intermediate positions of the slidable element;
varying the one or more application views associated with the intermediate positions on the basis of a moment in time; and
selecting the application view to be displayed depending on the moment in time when the one or more intermediate positions are detected.

19. The computer program distribution medium of claim 21, the process further comprising: maintaining a current application view on the display when a selection function is detected while the slidable element is in a given intermediate position; and activating an application related to the maintained application view once the slidable element has reached the open position or the closed position.

20. The computer program distribution medium of claim 21, the process further comprising: activating an application related to the displayed application view when the slidable element is in an intermediate position associated with the displayed application view.

21. A computer program distribution medium readable by a computer and encoding a computer program of instructions, which execute a computer process comprising:
controlling functions of an apparatus, the apparatus comprising: a body, a slidable element connected to the body, and a display connected to the body for displaying application views, wherein the slidable element is slidable between a closed position and an open position relative to the body;
detecting an occurrence of one or more intermediate positions of the slidable element relative to the body, the intermediate positions being associated with one or more application views and residing between the closed position and the open position;
controlling which predetermined application view is displayed on the display on the basis of the detected occurrence of one or more intermediate positions of the slidable element;
varying the one or more application views associated with the intermediate positions on the basis of a moment in time; and
selecting the application view to be displayed depending on the moment in time when the one or more intermediate positions are detected.

22. The computer program distribution medium of claim 21, the distribution medium including at least one of the following mediums: a computer readable medium, a program storage medium, a record medium, a computer readable memory, a computer readable software distribution package, a and a computer readable compressed software package.

23. The method of claim 3, wherein after the activation of the application the method further comprises detecting an occurrence of an open position, a closed position or at least one intermediate position of the slidable element relative to the body, the positions being associated with one or more application views of the activated application; and controlling which predetermined application view of the activated application is displayed on the display on the basis of the detected occurrence of one or more positions of the slidable element.

24. The apparatus of claim 10, wherein after the activation of the application, the processing unit is configured to detect an occurrence of an open position, a closed position or at least one intermediate position of the slidable element relative to the body, the positions being associated with one or more application views of the activated application; and controlling which predetermined application view of the activated application is displayed on the display on the basis of the detected occurrence of one or more positions of the slidable element.
